(19) United States
(12) Patent Application Publication
(10) Pub. No.: US 2025/0270434 A1
(43) Pub. Date: Aug. 28, 2025

(54) AZEOTROPIC AND AZEOTROPE-LIKE COMPOSITIONS COMPRISING 1,1,2,2-TETRAFLUOROETHYL-2,2,2-TRIFLUOROETHYL ETHER AND USES THEREOF

(71) Applicant: The Chemours Company FC, LLC, Wilmington, DE (US)

(72) Inventor: MICHAEL R. FRASER, Quakertown, PA (US)

(73) Assignee: The Chemours Company FC, LLC, Wilmington, DE (US)

(21) Appl. No.: 18/985,202

(22) Filed: Dec. 18, 2024

Related U.S. Application Data
(60) Provisional application No. 63/612,514, filed on Dec. 20, 2023.

(51) Int. Cl. C09K 5/04; H05K 7/20

(52) U.S. Cl. CPC C09K 5/048; H05K 7/203; H05K 7/20318

(57) ABSTRACT

The present disclosure provides azeotropic and azeotrope-like compositions including 1,1,2,2-tetrafluoroethyl-2,2,2-trifluoroethyl ether. The present disclosure also provides for methods of use for the azeotropic and azeotrope-like compositions. The azeotropic and azeotrope-like compositions are particularly useful in cooling applications.

### FIELD OF DISCLOSURE

The present disclosure is in the field of 1,1,2,2-tetrafluoroethyl-2,2,2-trifluoroethyl ether compositions. These compositions are azeotropic or azeotrope-like and are particularly useful in cooling applications.

### BACKGROUND

The use of two-phase immersion cooling has become an increasingly popular method for thermal management in emerging technologies, like data center servers and computers, due to the very reliably narrow range of operating temperatures, high efficiency, and simplicity compared to closed-loop single phase cooling methods. Such closed-loop single phase cooling methods require pumps, heat exchangers, fans, and thermostats, among other components, to maintain a given temperature range, and therefore require more complex setups compared to two-phase immersion cooling.

Two-phase immersion cooling relies on the boiling of an immersion coolant to remove heat from the device it is in direct contact with, and thus maintains the operating temperature at the boiling point of the fluid. Ideally, effective immersion cooling fluids in direct contact with electrically charged components require a low dielectric constant, high breakdown voltage, and excellent thermal stability and material compatibility for constant, long-term interaction with all components of the device it is cooling. Additionally, two-phase immersion fluids must be non-flammable and have a boiling point within the desired operating temperature of the device.

Perfluorocarbons, such as perfluoro(N-methylmorpholine) (e.g., Fluorinert™ FC-3284) and perfluorohexane (e.g., Fluorinert™ FC-72), and perfluoroketones, such as perfluoroethyl isopropyl ketone (e.g., Novec™ 649), have commonly been used in two-phase immersion cooling applications. Such perfluorocarbons and perfluoroketones have boiling points between 50° C. and 60° C., respectively, and dielectric constants of less than 2. However, these perfluorinated fluids typically have very low latent heat of vaporization and low thermal conductivity.

In addition, per- and polyfluoroalkyl substances (PFAS), which include a chemical structure that contains the unit R—CF₂—CF(R′)(R″), where R, R′, and R″ do not equal H and the carbon-carbon bond is saturated, and where branching, heteroatoms, and cyclic structures are included, have potential health and ecological effects. Therefore, the use of PFAS is subject to governmental restrictions and safety considerations.

With the advancements in high performance computing and the need for processors running at higher clock rates, there is a need for non-PFAS-based immersion fluids with higher thermal conductivity and higher latent heat of vaporization to enable reliable operation of central processing units (CPU's) and graphics processing units (GPU's) at higher frequencies while maintaining surface temperatures within their design limits. There is also a need for overall higher operational efficiency and less energy consumption by water-cooled condensing systems that typically include water pumps and radiator fans.

### BRIEF DESCRIPTION

The present disclosure provides an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

The present disclosure also provides an immersion cooling unit including an immersion cell defining an internal cavity. An electronic or electrical component is positioned in the internal cavity. A dielectric working fluid partially fills the internal cavity and at least partially immerses the energy storage device, IT equipment, computer server etc. The dielectric working fluid includes an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

The present disclosure also provides a method for cooling electrically charged equipment, such as but not limited to energy storage devices (such as batteries), IT equipment, computer servers including those used in data centers and crypto currency mining applications. The method includes at least partially immersing an electrical component in a working fluid; and transferring heat from the electrical component using the working fluid; wherein the working fluid comprises an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

The present disclosure also provides a method for replacing a dielectric fluid in an immersion cooling system. The method includes charging an immersion cooling system that was designed for use with a working fluid with an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

### BRIEF DESCRIPTION OF THE DRAWINGS

Embodiments are illustrated in the accompanying figures to improve understanding of concepts as presented herein.

FIG. 1 is a perspective view of an immersion unit in accordance with the present disclosure.

FIG. 2 is a perspective view of an immersion unit in accordance with the present disclosure.

FIG. 3 is a pool boiling curve in accordance with the present disclosure.

FIG. 4 depicts a vapor-liquid equilibrium curve for mixtures of PEIK and HFE-347pcF in accordance with the present disclosure.

FIG. 5 depicts a vapor-liquid equilibrium curve for mixtures of perfluorohexane and HFE-347pcF in accordance with the present disclosure.

FIG. 6 depicts a vapor-liquid equilibrium curve for mixtures of FC-3284 and HFE-347pcF in accordance with the present disclosure.

FIG. 7 depicts a vapor-liquid equilibrium curve for mixtures of nonafluorobutyl methyl ether and HFE-347pcF in accordance with the present disclosure.

### DETAILED DESCRIPTION

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present disclosure, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

Many aspects and embodiments have been described above and are merely exemplary and not limiting. After reading this specification, skilled artisans appreciate that other aspects and embodiments are possible without departing from the scope of the invention.

Described herein are azeotropic and azeotrope-like compositions of 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether, as described below. Also described herein are novel methods of using an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

In some embodiments, the nonafluorobutyl methyl ether comprises a mixture of nonafluoro-n-butyl methyl ether and nonafluoro-sec-butyl ethyl ether. In some embodiments, nonafluorobutyl ethyl ether comprises a mixture of nonafluoro-n-butyl ethyl ether and nonafluoro-sec-butyl ethyl ether. Nonafluorobutyl methyl ether and Nonafluorobutyl ethyl ether are available from 3M Corporation as Novec 7100 and Novec 7200 respectively.

As used herein, an azeotropic composition is a constant boiling liquid admixture of two or more substances wherein the admixture distills without substantial composition change and behaves as a constant boiling composition. Constant boiling compositions, which are characterized as azeotropic, exhibit either a maximum or a minimum boiling point, as compared with that of the non-azeotropic mixtures of the same substances. In one embodiment, an azeotropic composition is a specific composition of two or more substances which exhibits a constant minimum or maximum temperature. In another embodiment, an azeotropic composition is a mixture of two or more substances which exhibits a constant minimum or maximum temperature over a range of compositions. Azeotropic compositions include homogeneous azeotropes which are liquid admixtures of two or more substances that behave as a single substance, in that the vapor, produced by partial evaporation or distillation of the liquid, has the same composition as the liquid. Azeotropic compositions, as used herein, also include heterogeneous azeotropes where the liquid phase splits into two or more liquid phases. In these embodiments, at the azeotropic point, the vapor phase is in equilibrium with two liquid phases and all three phases have different compositions. If the two equilibrium liquid phases of a heterogeneous azeotrope are combined and the composition of the overall liquid phase calculated, this would be identical to the composition of the vapor phase.

As used herein, the term “azeotrope-like composition” also sometimes referred to as “near azeotropic composition,” means a constant boiling, or substantially constant boiling liquid admixture of two or more substances that behaves as a single substance. One way to characterize an azeotrope-like composition is that the vapor produced by partial evaporation or distillation of the liquid has substantially the same composition as the liquid from which it was evaporated or distilled. That is, the admixture distills or refluxes without substantial composition change. Alternatively, an azeotrope-like composition may be characterized as a composition having a boiling point temperature of less than the boiling point of each pure component.

Further, yet another way to characterize an azeotrope-like composition is that the bubble point pressure of the composition and the dew point vapor pressure of the composition at a particular temperature are substantially the same. Azeotrope-like compositions exhibit dew point pressure and bubble point pressure with virtually no pressure differential. Hence, the difference in the dew point pressure and bubble point pressure at a given temperature will be a small value. It may be stated that compositions with a difference in dew point pressure and bubble point pressure of less than or equal to 3 percent (based upon the bubble point pressure) may be considered to be azeotrope-like.

In another embodiment, azeotrope-like compositions exhibit a boiling vapor at a temperature within 0.1° C. of the minimum or maximum boiling temperature of the azeotropic composition. In another embodiment, azeotrope-like compositions exhibit a boiling vapor at a temperature within 0.5° C. of the minimum or maximum boiling temperature of the azeotropic composition. In yet another embodiment, azeotrope-like compositions exhibit a boiling vapor at a temperature within 1.0° C. of the minimum or maximum boiling temperature of the azeotropic composition.

A composition of one embodiment of the invention comprises 1,1,2,2-tetrafluoroethyl-2,2,2-trifluoroethyl ether and an effective amount of a component selected from the group consisting of perfluoroethyl isopropyl ketone, perfluorohexane, perfluoro(N-methylmorpholine), and nonafluorobutyl methyl ether to form an azeotropic composition. An “effective amount” is defined as an amount which, when combined with 1,1,2,2-tetrafluoroethyl-2,2,2-trifluoroethyl ether, results in the formation of an azeotropic or near-azeotropic mixture.

Compositions may be formed that comprise azeotropic or azeotrope-like combinations of 1,1,2,2-tetrafluoroethyl-2,2,2-trifluoroethyl ether and component selected from the group consisting of perfluoroethyl isopropyl ketone, perfluorohexane, perfluoro(N-methylmorpholine), and nonafluorobutyl methyl ether. In one embodiment these include compositions comprising 1,1,2,2-tetrafluoroethyl-2,2,2-trifluoroethyl ether and perfluoroethyl isopropyl ketone. In another embodiment, these include compositions comprising 1,1,2,2-tetrafluoroethyl-2,2,2-trifluoroethyl ether and perfluorohexane. In yet another embodiment, these include compositions comprising 1,1,2,2-tetrafluoroethyl-2,2,2-trifluoroethyl ether and perfluoro(N-methylmorpholine). In yet another embodiment, these include compositions comprising 1,1,2,2-tetrafluoroethyl-2,2,2-trifluoroethyl ether and nonafluorobutyl methyl ether.

In one embodiment, the azeotropic compositions comprise from about 19 weight percent to about 32 weight percent 1,1,2,2-tetrafluoroethyl-2,2,2-trifluoroethyl ether, and from 68 weight percent to about 81 weight percent perfluoroethyl isopropyl ketone. In another embodiment, the azeotropic compositions comprise from about 27 weight percent to about 62 weight percent 1,1,2,2-tetrafluoroethyl-2,2,2-trifluoroethyl ether, and from about 38 weight percent to about 73 weight percent perfluorohexane. In yet another embodiment, the azeotropic compositions comprise from about 22 weight percent to about 50 weight percent 1,1,2,2-tetrafluoroethyl-2,2,2-trifluoroethyl ether, and from about 50 weight percent to about 78 weight percent perfluoro(N-methylmorpholine). In yet another embodiment, the azeotropic compositions comprise from about 48 weight percent to about 84 weight percent 1,1,2,2-tetrafluoroethyl-2,2,2-trifluoroethyl ether, and from about 16 weight percent to about 52 weight percent nonafluorobutyl methyl ether.

In one embodiment, the azeotropic compositions consist essentially of from about 19 weight percent to about 32 weight percent 1,1,2,2-tetrafluoroethyl-2,2,2-trifluoroethyl ether, and from 68 weight percent to about 81 weight percent perfluoroethyl isopropyl ketone. In another embodiment, the azeotropic compositions consist essentially of from about 27 weight percent to about 62 weight percent 1,1,2,2-tetrafluoroethyl-2,2,2-trifluoroethyl ether, and from about 38 weight percent to about 73 weight percent perfluorohexane. In yet another embodiment, the azeotropic compositions consist essentially of from about 22 weight percent to about 50 weight percent 1,1,2,2-tetrafluoroethyl-2,2,2-trifluoroethyl ether, and from about 50 weight percent to about 78 weight percent perfluoro(N-methylmorpholine). In yet another embodiment, the azeotropic compositions consist essentially of from about 48 weight percent to about 84 weight percent 1,1,2,2-tetrafluoroethyl-2,2,2-trifluoroethyl ether, and from about 16 weight percent to about 52 weight percent nonafluorobutyl methyl ether.

In one embodiment, the azeotropic compositions consist of from about 19 weight percent to about 32 weight percent 1,1,2,2-tetrafluoroethyl-2,2,2-trifluoroethyl ether, and from 68 weight percent to about 81 weight percent perfluoroethyl isopropyl ketone. In another embodiment, the azeotropic compositions consist of from about 27 weight percent to about 62 weight percent 1,1,2,2-tetrafluoroethyl-2,2,2-trifluoroethyl ether, and from about 38 weight percent to about 73 weight percent perfluorohexane. In yet another embodiment, the azeotropic compositions consist of from about 22 weight percent to about 50 weight percent 1,1,2,2-tetrafluoroethyl-2,2,2-trifluoroethyl ether, and from about 50 weight percent to about 78 weight percent perfluoro(N-methylmorpholine). In yet another embodiment, the azeotropic compositions consist of from about 48 weight percent to about 84 weight percent 1,1,2,2-tetrafluoroethyl-2,2,2-trifluoroethyl ether, and from about 16 weight percent to about 52 weight percent nonafluorobutyl methyl ether.

In some embodiments, the compositions of the present application further comprise stabilizers that reduce degradation over time and elevated temperatures.

The present application provides azeotropic and azeotrope-like compositions comprising 1,1,2,2-tetrafluoroethyl-2,2,2-trifluoroethyl ether, a component selected from the group consisting of perfluoroethyl isopropyl ketone, perfluorohexane, perfluoro(N-methylmorpholine), and nonafluorobutyl methyl ether, and a component selected from the group consisting of linear hydrocarbons, cyclic hydrocarbons, cyclohexane, methylcyclohexane, n-heptane, and combinations thereof. In these embodiments, the compositions are ternary azeotropic and azeotrope-like compositions.

In one embodiment, the azeotropic compositions comprise from about 18 weight percent to about 26 weight percent 1,1,2,2-tetrafluoroethyl-2,2,2-trifluoroethyl ether, from about 63 weight percent to about 75 weight percent perfluoroethyl isopropyl ketone, and from about 4 weight percent to about 10 weight percent cyclohexane.

In one embodiment, the azeotropic compositions comprise from about 18 weight percent to about 30 weight percent 1,1,2,2-tetrafluoroethyl-2,2,2-trifluoroethyl ether, from about 67 weight percent to about 80 weight percent perfluoroethyl isopropyl ketone, and from about 1 weight percent to about 4 weight percent methylcyclohexane.

In one embodiment, the azeotropic compositions comprise from about 18 weight percent to about 30 weight percent 1,1,2,2-tetrafluoroethyl-2,2,2-trifluoroethyl ether, from about 68 weight percent to about 80 weight percent perfluoroethyl isopropyl ketone, and from about 1 weight percent to about 4 weight percent n-heptane.

In one embodiment, the azeotropic compositions comprise from about 20 weight percent to about 45 weight percent 1,1,2,2-tetrafluoroethyl-2,2,2-trifluoroethyl ether, from about 47 weight percent to about 74 weight percent perfluoro(N-methylmorpholine), and from about 4 weight percent to about 10 weight percent cyclohexane.

In one embodiment, the azeotropic compositions comprise from about 45 weight percent to about 80 weight percent 1,1,2,2-tetrafluoroethyl-2,2,2-trifluoroethyl ether, from about 15 weight percent to about 49 weight percent nonafluorobutyl methyl ether, and from about 2 weight percent to about 8 weight percent n-heptane.

In one embodiment, the azeotropic compositions consist essentially of from about 18 weight percent to about 26 weight percent 1,1,2,2-tetrafluoroethyl-2,2,2-trifluoroethyl ether, from about 63 weight percent to about 75 weight percent perfluoroethyl isopropyl ketone, and from about 4 weight percent to about 10 weight percent cyclohexane.

In one embodiment, the azeotropic compositions consist essentially of from about 18 weight percent to about 30 weight percent 1,1,2,2-tetrafluoroethyl-2,2,2-trifluoroethyl ether, from about 67 weight percent to about 80 weight percent perfluoroethyl isopropyl ketone, and from about 1 weight percent to about 4 weight percent methylcyclohexane.

In one embodiment, the azeotropic compositions consist essentially of from about 18 weight percent to about 30 weight percent 1,1,2,2-tetrafluoroethyl-2,2,2-trifluoroethyl ether, from about 68 weight percent to about 80 weight percent perfluoroethyl isopropyl ketone, and from about 1 weight percent to about 4 weight percent n-heptane.

In one embodiment, the azeotropic compositions consist essentially of from about 20 weight percent to about 45 weight percent 1,1,2,2-tetrafluoroethyl-2,2,2-trifluoroethyl ether, from about 47 weight percent to about 74 weight percent perfluoro(N-methylmorpholine), and from about 4 weight percent to about 10 weight percent cyclohexane.

In one embodiment, the azeotropic compositions consist essentially of from about 45 weight percent to about 80 weight percent 1,1,2,2-tetrafluoroethyl-2,2,2-trifluoroethyl ether, from about 15 weight percent to about 49 weight percent nonafluorobutyl methyl ether, and from about 2 weight percent to about 8 weight percent n-heptane.

In one embodiment, the azeotropic compositions consist of from about 18 weight percent to about 26 weight percent 1,1,2,2-tetrafluoroethyl-2,2,2-trifluoroethyl ether, from about 63 weight percent to about 75 weight percent perfluoroethyl isopropyl ketone, and from about 4 weight percent to about 10 weight percent cyclohexane.

In one embodiment, the azeotropic compositions consist of from about 18 weight percent to about 30 weight percent 1,1,2,2-tetrafluoroethyl-2,2,2-trifluoroethyl ether, from about 67 weight percent to about 80 weight percent perfluoroethyl isopropyl ketone, and from about 1 weight percent to about 4 weight percent methylcyclohexane.

In one embodiment, the azeotropic compositions consist of from about 18 weight percent to about 30 weight percent 1,1,2,2-tetrafluoroethyl-2,2,2-trifluoroethyl ether, from about 68 weight percent to about 80 weight percent perfluoroethyl isopropyl ketone, and from about 1 weight percent to about 4 weight percent n-heptane.

In one embodiment, the azeotropic compositions consist of from about 20 weight percent to about 45 weight percent 1,1,2,2-tetrafluoroethyl-2,2,2-trifluoroethyl ether, from about 47 weight percent to about 74 weight percent perfluoro(N-methylmorpholine), and from about 4 weight percent to about 10 weight percent cyclohexane.

In one embodiment, the azeotropic compositions consist of from about 45 weight percent to about 80 weight percent 1,1,2,2-tetrafluoroethyl-2,2,2-trifluoroethyl ether, from about 15 weight percent to about 49 weight percent nonafluorobutyl methyl ether, and from about 2 weight percent to about 8 weight percent n-heptane.

The present application provides compositions, comprising 1,1,2,2-tetrafluoroethyl-2,2,2-trifluoroethyl ether azeotrope compositions and an additional component selected from the group consisting of one or more antioxidants and one or more acid scavengers, or any mixture thereof.

In some embodiments, the one or more acid antioxidants are selected from butylated hydroxy toluene (BHT), hydroquinone monomethyl ether (HQMME), 2-tert-butyl-6-methylphenol, 2-tert-butyl-5-methylphenol and 2-tert-butyl-4-ethylphenol. In some embodiments, the one or more scavengers are selected from 1,3-dioxolane, 1,2-epoxybutane and nitromethane.

Large scale computer server systems can perform significant workloads and generate a large amount of heat during their operation. A significant portion of the heat is generated from their operation. Due in part to the amount of heat generated, these systems are typically mounted in stacked configurations with large internal cooling fans and heat dissipating fins. As the size and density of these systems increases the thermal challenges are even greater, and eventually outpace the ability for forced air systems.

Two-phase immersion cooling is an emerging cooling technology for the high performance cooling market as applied to high performance high power density server systems, IT equipment used in Data centers, crypto currency mining facilities. It relies on the heat absorbed in the process of vaporizing an immersion liquid into a gas. The fluids used in this application must meet certain requirements to be viable in use. For example, the boiling temperature of the fluid should be in the range between 30-75° C. Generally, this range accommodates maintaining the server components at a sufficiently cool temperature while allowing generated heat to be dissipated sufficiently to an external heat sink. Alternatively, the operating temperature of the server, and the immersion cooling system could be raised or lowered, by using an enclosed system and raising or lowering the pressure within the system to raise or lower the boiling point of a given fluid.

Single phase immersion cooling has a long history in computer server cooling. There is no phase change in single phase immersion cooling. Instead, the liquid warms as it circulates through the computer server or heat generating device, and then is circulated with a pump to a heat exchanger for cooling prior to returning to the server or heat generating device, thus transferring heat away from those components. Fluids used for single phase immersion cooling have the same requirements as those for two-phase immersion cooling, except that the boiling temperatures are typically higher than 30-75° C., to reduce loss by evaporation.

Provided is an immersion cooler having an operating temperature range near ambient temperatures. Some embodiments of the present disclosure, for example, in comparison to concepts failing to include one or more of the features disclosed herein, provide an immersion cooler having fluids for thermal management which are environmentally friendly (i.e., have a low global warming potential (GWP) and low ozone depletion potential (ODP)). Some embodiments of the present disclosure, for example, in comparison to concepts failing to include one or more of the features disclosed herein, provide an immersion cooler having fluids for thermal management which are not PFAS-based immersion fluids.

Also provided is a method of immersion cooling wherein the device is a heat generating component, comprising at least partially immersing the heat generating component into the immersion cooling fluid in a liquid state, and transferring heat from the heat generating component using the immersion cooling fluid. Such devices include high capacity energy storage devices, electrical components, IT equipment, computer servers, mechanical components and optical components. Examples of devices of the present disclosure include, but are not limited to, microprocessors, wafers used to manufacture semiconductor devices, power control semiconductors, electrical distribution switch gear, power transformers, circuit boards, multi-chip modules, packaged and unpackaged semiconductor devices, laser, fuel cells, electrochemical cells and energy storage devices such as batteries. In some embodiments, the device is an electronic component selected from: high-capacity energy storage devices, computer servers, datacenter servers, GPUs, CPUs, solar photovoltaics, batteries, insulated-gate bipolar transistor (IGBT) devices, telecommunication infrastructure, military electronics, televisions, cell phones, monitors, drones, automotive batteries, powertrains for electric vehicles, power electronics, avionics devices, power devices, power transformers, displays, microprocessors, wafers used to manufacture semiconductor devices, power control semiconductors, electrical distribution switch gear, circuit boards, multi-chip modules, packaged and unpackaged semiconductor devices, lasers, fuel cells, electrochemical cells, and combinations thereof. In some embodiments the device can include a chiller, a heater, or a combination thereof.

In certain embodiments, the devices can include electronic devices, such as processors, including microprocessors. Microprocessors typically have maximum operating temperatures of about 85° C., so effective heat transfer is required in conditions of high processing power, i.e. high heat rejection rates. In other embodiments, the devices may include energy storage systems, such as batteries. When rapidly charged or discharged, batteries can reject a significant amount of heat that needs to be effectively removed to avoid overheating, internal damage, thermal runaway to adjacent batteries and potentially fire. As these electronic and electric devices become denser, and more powerful, the amount heat generated per unit of time and volume increases. Therefore, the mechanism of heat transfer plays an important role in processor performance. The heat transfer fluid typically has good heat transfer performance, good electrical compatibility (even if used in “indirect contact” applications such as those employing cold plates), as well as low toxicity, low or nonflammability and low environmental impact. Good electrical compatibility suggests that the heat-transfer fluid candidate exhibit high dielectric strength, high volume resistivity, low dissipation factor, low dielectric constant and poor solvency for polar materials. Additionally, the heat-transfer fluid should exhibit good material compatibility, that is, it should not affect typical materials of construction in an adverse manner.

It is generally understood that perfluorinated liquids, such as Fluorinert FC-72 and FC-3284, may exhibit excellent dielectric properties such as dielectric constants of 2.0 or less, high volume resistivity on the order of 10¹⁵ ohm-cm and high dielectric strength. It is also generally understood that hydrofluoroethers (HFEs) typically have lower GWP's.

In one embodiment, the GWP of a working fluid is less than 600. In another embodiment, the GWP of a working fluid is less than 500. In another embodiment, the GWP of a working fluid is less than 100. In another embodiment, the compositions disclosed have a Global Warming Potential (GWP) of not greater than 50. As used herein, “GWP” is measured relative to that of carbon dioxide and over a 100-year time horizon, as defined in AR4 of the IPCC (Intergovernmental Panel on Climate Change).

It is highly desirable that the new fluids have equivalent or superior heat transfer properties, including electronic surface-to-fluid thermal resistance, critical heat flux and fluid-to-condenser thermal resistance, compared to existing fluids so that they can replace these fluids in existing systems without significant loss in thermal performance or mechanical modifications; and in new systems designed for existing fluids without significant mechanical design changes. The practice of replacing an existing fluid with a new fluid in an existing system is often called “retrofit”.

It is also desirable that these fluids have similar normal boiling points compared to existing fluids so that they can be used to replace these in existing systems without significant mechanical or operational changes; and in new systems without significant mechanical design changes.

It is also highly desirable that the new fluids provide at least minimum dielectric properties required by the application, or even superior dielectric properties compared to existing fluids so that they can replace these fluids in existing systems without significant electrical or mechanical modifications; and in new systems designed for existing fluids without significant electrical or mechanical design changes. The desirable dielectric properties include high volume resistivity, low dielectric constant, high dielectric strength and low loss tangent.

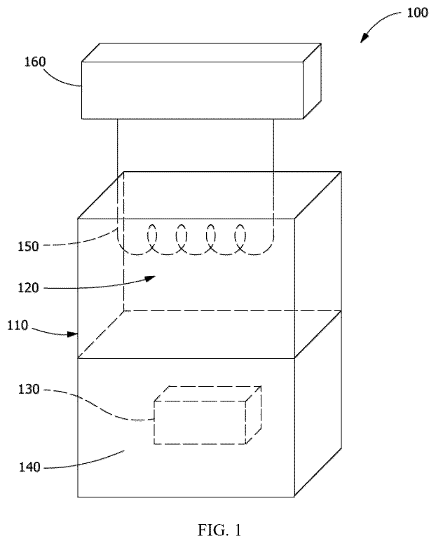

An embodiment of an immersion cooling unit 100 is shown in FIG. 1. The immersion cooling system 100 includes an immersion cell 110 defining an internal cavity 120. A heat generating electrically charged component, (such as an energy storage device) 130, to be cooled, may be placed in the internal cavity 120. A dielectric working fluid 140 partially fills the internal cavity 120. The dielectric working fluid 140 at least partially immerses the energy storage device 130. In some embodiments, the dielectric working fluid 140 substantially immerses the energy storage device 130. In one embodiment, the dielectric working fluid 140 completely immerses the energy storage device 130. A condenser 150 (i.e., a heat transfer device) is additionally present in the internal cavity 120. The condenser 150 may be spatially located above at least a portion of the dielectric working fluid 140.

During operation, heat generated by the electrical component 130, heats the dielectric working fluid 140 causing a portion of the dielectric working fluid 140 to vaporize. The dielectric working fluid 140 vapors contact the condenser 150 above the dielectric working fluid 140 and transfer thermal energy to the condenser 150 allowing the condensate dielectric working fluid 140 to precipitate back into the liquid dielectric working fluid 140 below. The thermal energy transferred to the condenser 150 is transported external to the immersion cell 110 and released into the environment or to a chiller via a heat exchanger 160. The thermal energy released can also be recovered and used for heating applications or for energy generation such as Rankine cycles.

The dielectric working fluids of the immersion cooler 100 are selected to undergo a phase transition from the liquid to the gaseous state over the operational temperature range of the immersion cooler 100. In some embodiments, the composition of the dielectric working fluids 140 includes one or more hydrofluoroether compounds. In some embodiments, the operational temperature is at least 25° C., at least 30° C., at least 40° C., at least 50° C., at least 60° C., less than 100° C., less than 90° C., less than 80° C., less than 70° C., less than 60° C., and combinations thereof.

In one embodiment the normal boiling point of the new dielectric fluid may be within at least 10° C. of the fluid being replaced. In another embodiment the normal boiling point of the new dielectric fluid may be within 8° C. In yet another embodiment, the normal boiling point of the new dielectric fluid may be within 5° C.

The dielectric working fluids 140 may also be selected to exhibit a dielectric constant, volume resistivity, dielectric strength and loss tangent (dissipation factor) suitable for direct contact with electrical components. In general, materials exhibiting a low dielectric constant, low loss tangent or dissipation factor, high volume resistivity and large dielectric strength provide increased electrical insulation of the energy storage device, or electrically charged components, 130, immersed therein as well as reduced signal loss. In some embodiments, the dielectric constant of the dielectric working fluids 140 is less than about 8 over the operational frequency range (which can go as high as 100 GHz). Suitable dielectric working fluids include compounds and mixtures having a dielectric constant over the operational frequency range (up to about 100 GHz) of less than 7.3, or less than 5.5, or less than 5.0, or less than 4.0, or less than 3.5, or less than 2.7. Other embodiments include compounds and mixtures having a dielectric constant greater than 1.0 and less than 8.0 or greater than 2.0 and less than 7.3 or greater than 2.5 and less than 5.5 or greater than 3.5 and less than 5.0.

Another characteristic of a good working fluid is that it possesses a high volume resistivity. Volume resistivity is an intrinsic property which measures how strongly a material resists electric current per unit length of a unit cross section, typically expressed in units of ohm-cm or ohm-m. A higher volume resistivity means the material is a better electrical insulator. The electrical resistance of material can be calculated by multiplying volume resistivity by the length and dividing by the cross-sectional area of the material.

So, a higher volume resistivity dielectric fluid is desirable as it leads to a higher electrical resistance and, consequently, a lower current leakage. Current leakage, for instance, can lead to self-discharge of energy storage devices such as batteries. It also means electrical components with different voltage can be placed closer (smaller “L”) for a given minimum resistance requirement, potentially leading to more compact assemblies. In one embodiment effective working fluids have a volume resistivity, measured at 25° C. of at least 1×10¹⁰ ohm-cm. In another embodiment, an effective working fluid has a volume resistivity of at least 1×10¹¹ ohm-cm. In another embodiment, an effective working fluid has a volume resistivity of at least 1×10¹² ohm-cm. Water is known for having much lower volume resistivity. Thus, fluids with high volume resistivity are also desirable as, in case of the presence of water in the fluid, they would still maintain adequate levels of actual volume resistivity.

Another important dielectric fluid property is the dielectric strength which is defined as the maximum electric field or voltage, per unit of length, a material can resist without undergoing electrical breakdown and becoming electrically conductive. It is typically measured in units of kV/mm or kV/0.1″ gap. For a given distance or “gap”, the voltage at which a material becomes electrically conductive is called the breakdown voltage. A higher dielectric strength material is advantageous since it allows a higher voltage between two conductors or it allows two conductors to be placed closer, leading to potentially more compact assemblies. In one embodiment, the dielectric strength is greater than about 10 kV/0.1″ gap. In another embodiment, the dielectric strength is greater than about 20 kV/0.1″ gap. In yet another embodiment, the dielectric strength is greater than about 30 kV/0.1″ gap. In yet another embodiment, the dielectric strength is greater than about 35 kV/0.1″ gap.

Dielectric loss tangent, sometimes called a dissipation factor, is another critical dielectric property particularly in high frequencies due to its impact on signal attenuation or signal loss. It is defined with the tan(δ), which is the ration of the imaginary component to the relative real component of the permittivity. It is also a measure of the rate at which energy carried by the electromagnetic field (RF) traveling through a dielectric is absorbed by that dielectric, i.e. it quantifies the dissipation of electromagnetic energy in the form of heat. Furthermore, the loss tangent is highly dependent on frequency and can increase particularly above frequencies of 1 GHz which can be found in applications such as data center, 5G and Wi-fi technology. More importantly, the signal loss or attenuation per unit length, typically measured in terms of dB/cm is proportional to the loss tangent. In other words, for a signal travelling through a dielectric fluid, the higher the loss tangent of the fluid, the higher the signal loss per unit length and consequently the shorter the distance it can travel. Thus, it is very desirable that dielectric fluids have low loss tangent values in frequencies above 1 GHz to up to about 100 GHz. The fluids discovered by the inventors have shown very favorable values of loss tangent at high frequencies.

All desirable dielectric properties aforementioned, high dielectric strength, low dielectric constant, low loss tangent and high volume resistivity must be present primarily in the liquid phase but also in the vapor phase.

Other desirable characteristic of an immersion cooling fluid relates its ability of not significantly damaging, or not significantly reacting with, IT and computer parts such as cables, wires, seals, metals, among other parts, as well as constructions materials of the tank which are exposed to the dielectric fluid.

It is also desirable that these fluids have similar interactions with electronic components compared to the existing fluids so to minimize the replacement of parts.

Contaminant control measures, such as filter systems, may be used to remove solid or liquid residues that may be generated as a result of reactivity with materials of construction. Contamination control measures can also be used to maintain low enough acid and water levels.

Typical non-condensable gases, such nitrogen and oxygen, can also be present in the dielectric fluid and can be detrimental to boiling and condensation heat transfer. Thus, systems with dielectric two-phase fluids may be equipped with a supplemental device that at least partially removes or controls the level of non-condensable levels in the dielectric fluid.

The ability of the working fluid 140 to transport heat is related to the heat of vaporization of the dielectric working fluid 140. Typically, the greater the heat of vaporization of the dielectric working fluids 140, the greater amount of energy that the working fluid 140 will absorb during vaporization and transport to the condenser 150 to be released during condensation.

Heats of vaporization for substances within the scope of the present disclosure are shown in the below table.

| Substance | ΔHᵥₐₚ (kJ/kg) |
|---|---|
| 1,1,2,2-tetrafluoroethyl- | 153 |
| 2,2,2-trifluoroethyl ether | |
| perfluoroethyl isopropyl ketone | 88 |
| perfluorohexane | 88 |
| perfluoro(N-methylmorpholine) | 105 |
| nonafluorobutyl methyl ether | 118 |
| cyclohexane | 356 |
| methylcyclohexane | 318 |
| n-heptane | 316 |

It is also desirable that these fluids are non-flammable or present no flash point. Standards such as ASTM D56, D1310, and E681 can be used to assess flammability.

Since the objective of these fluids is to remove heat from energy storage devices, one important consideration is how good of a two-phase heat transfer the dielectric fluid is. More specifically, how good of a heat transfer these fluids are under pool boiling conditions. Pool boiling heat transfer is typically divided into different modes or regimes:
1) Free convection: happens at small values of “wall superheat” or “excess temperature”—the difference between saturation temperature of the fluid and the wall or surface temperature
2) Nucleate boiling: occurs when there is high enough superheat for bubbles to form and separate from the surface, significantly improving heat transfer coefficient and heat flux. This mode is typically the preferred regime of boiling operation for heat removal. The nucleation boiling region is limited by the Critical Heat Flux (CHF) with units of kW/m². Heat transfer devices are usually designed to operate at heat fluxes lower than the CHF. The critical heat flux is particular to each fluid and depends on several thermophysical properties. It can be experimentally measured or estimated through semi-empirical models such as the one by Zuber (1958). Fluids with higher CHFs are desirable because they can remove more heat per unit of area, for a given wall superheat.
3) Transition boiling: a vapor film begins to form in the surface and there is an oscillation between nucleate and film boiling. The regime is unstable and not desirable to operate.
4) Film boiling: In this region the wall superheat is so high that a vapor blanket forms between the liquid and the surface—significantly reducing heat transfer coefficients. This region is also not desirable to operate.

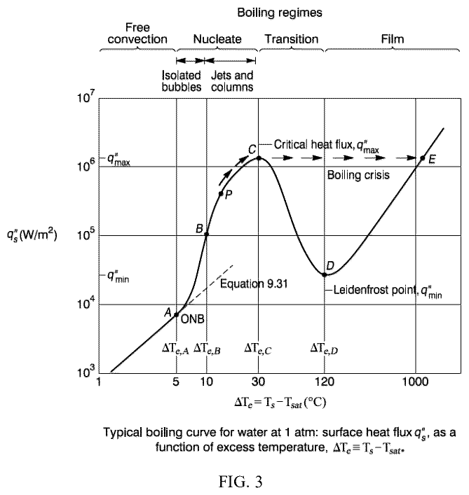

These regimes are illustrated in FIG. 3.

The present compositions may have improved CHFs compared to some existing fluids.

In one embodiment, it is highly desirable that the new fluids provide an equivalent or higher critical heat flux than the existing fluids they are replacing. In another embodiment, the new fluids should provide a critical heat flux of no less than 90% of the critical heat flux of the existing fluids they are replacing. In yet another embodiment, the new fluid should provide a critical heat flux of no less than 80% of the critical heat flux of the existing fluids they are replacing so that there are no significant changes to the maximum heat flux dissipation in an existing immersion cooling system or major design changes to immersion cooling systems designed for existing fluids.

A higher boiling heat transfer coefficient is desirable as it leads to a lower overall thermal resistance, or a lower temperature of the electrical component being cooled. The boiling heat transfer coefficient and the electrical component-to-fluid thermal resistance can be improved with the use of surface enhancements which increase the number of nucleation sites.

The electrical component-to-fluid thermal resistance can be determined by the inverse of the product between boiling heat transfer coefficient and the heat transfer area of the electronic/electrical component.

In one embodiment, the electrical component-to-fluid thermal resistance of the new fluids must be lower or equivalent compared to the existing fluid. In another embodiment, the electrical component-to-fluid thermal resistance of the new fluids must be no more than 10% higher than that of the existing fluid. In yet another embodiment, the electrical component-to-fluid thermal resistance of the new fluids must be no more than 20% higher than that of the existing fluid, so there is no significant increase in temperature of an existing electronic device or no significant mechanical changes have to be implemented in a system design for an existing fluid.

Another important aspect of fluids used in two-phase immersion cooling systems is its condensation heat transfer coefficient. Higher condensation heat transfer are desirable as they lead to reduced vapor-to-condenser surface thermal resistance or lower temperature difference between the condensing vapor and the coolant that removes the heat. Condensation heat transfer can also be improved with surface enhancements.

The vapor-to-condenser surface thermal resistance can be determined by the inverse of the product between condensation heat transfer coefficient and the heat transfer area of the condenser.

In one embodiment, the vapor-to-condenser thermal resistance of the new fluids must be lower or equivalent compared to an existing fluid. In another embodiment, the vapor-to-condenser thermal resistance of the new fluids must be no more than 10% higher compared to an existing fluid. In yet another embodiment, the vapor-to-condenser thermal resistance of the new fluids must be no more than 20% higher compared to an existing fluid, so there is no significant drop in condenser performance or no significant mechanical changes, for instance an increase in heat transfer area, have to be implemented in the condenser designed for an existing fluid.

Combined higher boiling and condensation heat transfer coefficients are highly desirable as they reduce the overall thermal resistance between the coolant and the electronic or electrical equipment and reduce the temperature difference between the two. Better heat transfer coefficients yield better heat removal which, for instance, can allow batteries immersed in a dielectric liquid to be charged at a faster rate without leading to potential thermal runaway.

Heat transfer coefficients can be experimentally measured or calculated using experimentally determined heat transfer correlations combined with experimentally determined thermophysical properties.

The power usage or efficiency of data centers can be quantified in terms of PUE—Power Utilization Effectiveness. The lower the PUE or the closer to 1.0, the lower the energy utilized to remove a given amount of heat from data centers. It is highly desirable that immersion tanks with dielectric fluids lead to operate at PUE values close to 1.0. The PUE of an immersion cooling tank can be obtained by measuring the overall energy dissipated by the immersed electronic equipment and the energy consumed by the tank. Due to equivalent dielectric, thermodynamic and heat transfer properties, the fluids proposed can also be used to replace existing fluids in existing equipment in a practice often called “retrofit”. The retrofit could be partial when only a percentage of the existing fluid is replaced or full, when the entire fluid is replaced with a new fluid.

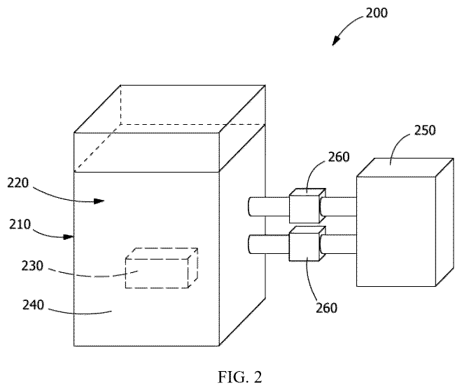

An embodiment of an immersion cooling unit 200 is shown in FIG. 2. The immersion cooling system 200 includes an immersion cell 210 defining an internal cavity 220. An energy storage device 230, to be cooled, may be placed in the internal cavity 220. A dielectric working fluid 240 partially fills the internal cavity 220. The dielectric working fluid 240 at least partially immerses the energy storage device 230. In some embodiments, the dielectric working fluid 240 substantially immerses the energy storage device 230. In one embodiment, the dielectric working fluid 240 completely immerses the energy storage device 230. A cooling unit 250 (i.e., a heat transfer device) is positioned externally to the immersion cell 210. The cooling unit 250 is fluidly connected to the immersion cell 210. The cooling unit 250 is configured to fluidly receive at least a portion of the dielectric working fluid 240 from the immersion cell 210. The cooling unit 250 is further configured to extract heat from the dielectric working fluid 240, thereby reducing the temperature of the dielectric working fluid 240. In one embodiment, the cooling unit 250 includes a heat exchanger. In one embodiment, the heat transferred to the cooling unit 250 is released into the environment. The cooling unit 250 is further configured to return the cooled dielectric working fluid 240 to the immersion cooling cell 210. In some embodiments, a motive force may be provided to the dielectric working fluid 240. In one embodiment, the motive force may be provided by one or more circulation pumps 260. In one embodiment, the motive force may be provided by convective flow.

The dielectric working fluids of the immersion cooler 200 are selected to be in the liquid state over the operational temperature range of the immersion cooler 200. In some embodiments, the composition of the dielectric working fluids 240 includes one or more hydrofluoroether compounds. In some embodiments, the operational temperature is at least 25° C., at least 30° C., at least 40° C., at least 50° C., at least 60° C., less than 100° C., less than 90° C., less than 80° C., less than 70° C., and combinations thereof.

Due to equivalent or better dielectric, thermodynamic and heat transfer properties, the fluids proposed can also be used to replace existing fluids in existing equipment in a practice often called “retrofit”.

From a practical perspective, liquid water is pushed up into the headspace of the device during startup and operation of the system. The presence of water in the cooling system (particularly in the headspace) is undesirable. It may contribute to corrosion of metal components in the headspace of the system. It may contribute to corrosion of metal components in the headspace of the system. The presence of water in the dielectric fluid can be detrimental to its dielectric properties since water has significantly lower resistivity (5×10⁵ ohm-cm for distilled water).

While the invention has been described with reference to one or more embodiments, it will be understood by those skilled in the art that various changes may be made, and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

### EXAMPLES

The concepts described herein will be further described in the following examples, which do not limit the scope of the invention described in the claims. Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification is to be regarded in an illustrative, rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

### Example 1. Binary Azeotropes

It was experimentally determined that binary mixtures of 1,1,2,2-tetrafluoroethyl-2,2,2-trifluoroethyl ether (HFE-347pcF) and the following components demonstrate azeotropic behavior.

TABLE 1
BINARY AZEOTROPES.

| | | | | Minimum |
|---|---|---|---|---|
| | | wt % | wt % | Boiling |
| Compo- | | HFE- | Component | Point |
| sition | Component B | 347pcF | B | (° C.) |
| B1 | Perfluoroethyl isopropyl | 19-32 | 68-81 | 44.5 |
| | ketone (PEIK) (e.g., | | | |
| | Novec ™ 649) | | | |
| B2 | Perfluorohexane (e.g., | 27-62 | 38-73 | 47 |
| | Fluorinert ™ FC-72) | | | |
| B3 | perfluoro(N- | 22-50 | 50-78 | 47.7 |
| | methylmorpholine) (e.g., | | | |
| | Fluorinert ™ FC-3284) | | | |
| B4 | Nonafluorobutyl methyl | 48-84 | 16-52 | 54.5 |
| | ether (e.g., Novec ™ | | | |
| | nonafluorobutyl methyl | | | |
| | ether) | | | |

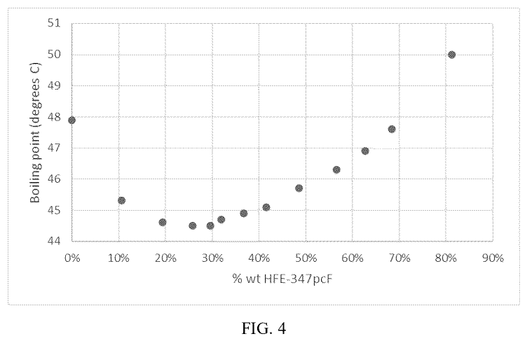

An ebulliometer apparatus was used to determine the azeotrope-like range of the HFE-347pcF and Component B mixtures. The apparatus included a flask with a thermocouple, heating mantle, and condenser. A side neck on the flask was fitted with a rubber septum to allow the addition of one component into the flask. Initially the flask contained 100% HFE-347pcF and the liquid was heated gradually until reflux and the boiling temperature was recorded to the nearest 0.1 deg C. Additions of a Component B were made into the flask through the side neck, at approximately 1 wt % increments. Each time an addition of a Component B was made, the flask boiling temperature was allowed to stabilize and then recorded. The Component B was added to the HFE-347pcF mixture in the flask until a composition of approximately 50 wt % HFE-347pcF and 50 wt % Component B was present. A similar experiment began with 100% Component B in the flask and HFE-347pcF was then added incrementally added to the flask, to again obtain about 50% Component B and 50% HFE-347pcF. In this way, the boiling temperatures of Component B and HFE-347pcF mixtures from 0 to 100% were obtained. The results are depicted in FIGS. 4-7.

As shown in FIG. 4, combinations of PEIK and HFE-347pcF demonstrated a minimum-boiling azeotrope properties from about 19% to about 32% HFE-347pcF by weight, with a boiling point of about 44.5° C., which is lower than the boiling points of both PEIK and HFE-347pcF.

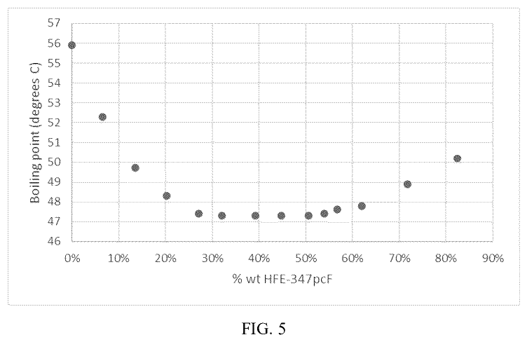

As shown in FIG. 5, combinations of perfluorohexane and HFE-347pcF demonstrated a minimum-boiling azeotropic properties from about 27% to about 62% HFE-347pcF by weight, with a boiling point of about 47° C., which is lower than the boiling point of both perfluorohexane and HFE-347pcF.

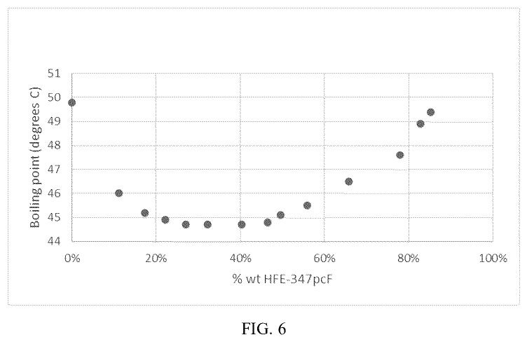

As shown in FIG. 6, combinations of FC-3284 and HFE-347pcF demonstrated minimum-boiling azeotropic properties from about 22% to about 50% HFE-347pcF by weight, with a boiling point of about 47.7° C., which is lower than the boiling point of both FC-3284 and HFE-347pcF.

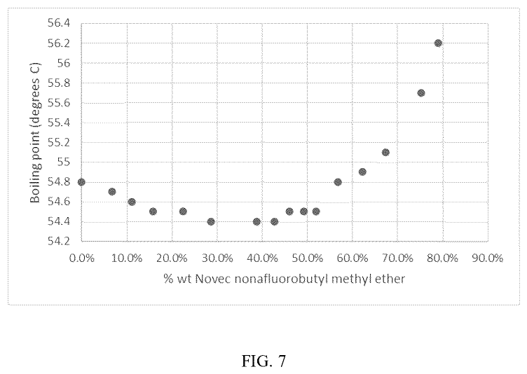

As shown in FIG. 7, combinations of nonafluorobutyl methyl ether and HFE-347pcF demonstrated a minimum-boiling azeotrope from about 48% to about 84% HFE-347pcF by weight, with a boiling point of about 54.5° C., which is lower than the boiling point of both nonafluorobutyl methyl ether and HFE-347pcF.

### Example 2. Ternary Azeotropes

It was experimentally determined that ternary mixtures of 1,1,2,2-tetrafluoroethyl-2,2,2-trifluoroethyl ether (HFE-347pcF) and the following components demonstrate azeotropic behavior.

TABLE 2
TERNARY AZEOTROPES.

| | | | wt % | wt % | wt % | Minimum |
|---|---|---|---|---|---|---|
| | Component | Component | HFE- | Component | Component | Boiling |
| Composition | B | C | 347pcF | B | C | Point (° C.) |
| T1 | PEIK | Cyclohexane | 22.1 | 70.4 | 7.5 | 42.9 |
| T2 | PEIK | Methylcyclohexane | 25.3 | 72.8 | 2.0 | 44.2 |
| T3 | PEIK | n-heptane | 25.2 | 72.9 | 2.0 | 44.2 |
| T4 | FC-3284 | cyclohexane | 26.4 | 65.8 | 7.8 | 47.7 |
| T5 | Nonafluoro | n-heptane | 65.0 | 30.0 | 5.0 | 53 |
| | butyl | | | | | |
| | methyl | | | | | |
| | ether | | | | | |

TABLE 3
AZEOTROPIC RANGES OF TERNARY COMPOSITIONS.

| | | | % wt | % wt | % wt | |
|---|---|---|---|---|---|---|
| | Component | Component | HFE- | Component | Component | |
| Composition | B | C | 347pcF | B | C | BP (° C.) |
| T1 | PEIK | Cyclohexane | 18-26 | 63-75 | 4-10% | 43 |
| T2 | PEIK | Methylcyclohexane | 18-30 | 67-80 | 1-4% | 44 |
| T3 | PEIK | n-Heptane | 18-30 | 68-80 | 1-4% | 44 |
| T4 | FC-3284 | Cyclohexane | 20-45 | 47-74 | 4-10% | 48 |
| T5 | Nonafluoro | n-Heptane | 45-80 | 15-49 | 2-8% | 53 |
| | butyl | | | | | |
| | methyl | | | | | |
| | ether | | | | | |

Atmospheric distillation techniques were used to determine the azeotrope-like range of the ternary compositions. Mixtures of each ternary combination were prepared and distilled using a 20 plate Vigreaux distillation column. The first 5% distillate from each distillation was secured and analyzed via a gas chromatograph with a flame ionization detector (FID). Ternary combinations with different starting compositions that converged on a narrow distillate composition were determined to be azeotropic.

Composition T1 was analyzed for dielectric properties per ASTM D924 and ASTM D1169 for dielectric constant and volume resistivity, and open cup flash point per ASTM D1310.

TABLE 4
DIELECTRIC PROPERTIES.

| | | | Vol. | | OC |
|---|---|---|---|---|---|
| | Dielectric | Dissipation | Resistivity | | Flash |
| Composition | constant | factor (%) | (Ω-cm) | GWP | point |
| T1 | 2.7 | 18.80 | 2.10E+11 | 130 | None |
| PEIK | 1.8 | 0.55 | 2.00E+12 | ~1 | None |
| Nonafluorobutyl | 7.4 | 148 | 2.30E+10 | 297 | None |
| methyl ether | | | | | |

As shown in Table 4, T1 demonstrated comparable dielectric properties to PEIK and nonafluorobutyl methyl ether and did not exhibit a flash point. Based on the weighted average of composition, the heat of vaporization of T1 is estimated to be around 35%-40% higher than neat PEIK and the thermal conductivity around 20% higher than PEIK. This improved heat dissipation, along with the reduced boiling point, may facilitate cooling applications and thereby enable higher clocking speeds for CPU's and GPU's before reaching a designed maximum chip surface temperature.

What is claimed is:

1. An azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

2. The azeotropic or azeotrope-like composition of claim 1, comprising from about 19 weight percent to about 32 weight percent 1,1,2,2-tetrafluoroethyl-2,2,2-trifluoroethyl ether, and from 68 weight percent to about 81 weight percent perfluoroethyl isopropyl ketone.

3. The azeotropic or azeotrope-like composition of claim 1, comprising from about 27 weight percent to about 62 weight percent 1,1,2,2-tetrafluoroethyl-2,2,2-trifluoroethyl ether, and from about 38 weight percent to about 73 weight percent perfluorohexane.

4. The azeotropic or azeotrope-like composition of claim 1, comprising from about 22 weight percent to about 50 weight percent 1,1,2,2-tetrafluoroethyl-2,2,2-trifluoroethyl ether, and from about 50 weight percent to about 78 weight percent perfluoro(N-methylmorpholine).

5. The azeotropic or azeotrope-like composition of claim 1, comprising from about 48 weight percent to about 84 weight percent 1,1,2,2-tetrafluoroethyl-2,2,2-trifluoroethyl ether, and from about 16 weight percent to about 52 weight percent nonafluorobutyl methyl ether.

6. The azeotropic or azeotrope-like composition of claim 1, further comprising a component selected from the group consisting of linear hydrocarbons, cyclic hydrocarbons, cyclohexane, methylcyclohexane, n-heptane, and combinations thereof, wherein the azeotropic or azeotrope-like composition is a ternary azeotropic or azeotrope-like composition.

7. The azeotropic or azeotrope-like composition of claim 1, comprising from about 18 weight percent to about 26 weight percent 1,1,2,2-tetrafluoroethyl-2,2,2-trifluoroethyl ether, from about 63 weight percent to about 75 weight percent perfluoroethyl isopropyl ketone, and from about 4 weight percent to about 10 weight percent cyclohexane.

8. The azeotropic or azeotrope-like composition of claim 1, comprising from about 18 weight percent to about 30 weight percent 1,1,2,2-tetrafluoroethyl-2,2,2-trifluoroethyl ether, from about 67 weight percent to about 80 weight percent perfluoroethyl isopropyl ketone, and from about 1 weight percent to about 4 weight percent methylcyclohexane.

9. The azeotropic or azeotrope-like composition of claim 1, comprising from about 18 weight percent to about 30 weight percent 1,1,2,2-tetrafluoroethyl-2,2,2-trifluoroethyl ether, from about 68 weight percent to about 80 weight percent perfluoroethyl isopropyl ketone, and from about 1 weight percent to about 4 weight percent n-heptane.

10. The azeotropic or azeotrope-like composition of claim 1, comprising from about 20 weight percent to about 45 weight percent 1,1,2,2-tetrafluoroethyl-2,2,2-trifluoroethyl ether, from about 47 weight percent to about 74 weight percent perfluoro(N-methylmorpholine), and from about 4 weight percent to about 10 weight percent cyclohexane.

11. The azeotropic or azeotrope-like composition of claim 1, comprising from about 45 weight percent to about 80 weight percent 1,1,2,2-tetrafluoroethyl-2,2,2-trifluoroethyl ether, from about 15 weight percent to about 49 weight percent nonafluorobutyl methyl ether, and from about 2 weight percent to about 8 weight percent n-heptane.

12. An immersion cooling unit comprising:
an immersion cell, defining an internal cavity;
i) an electronic component in the internal cavity;
ii) a dielectric working fluid partially filling the internal cavity;
iii) a heat transfer device, positioned in the internal cavity above the electronic component;
wherein the dielectric working fluid at least partially immerses the electronic component; and
wherein the dielectric working fluid includes an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

13. The immersion cooling unit of claim 12, wherein the heat transfer device is a condenser positioned in the internal cavity above the electronic component.

14. The immersion cooling unit of claim 12, wherein the heat transfer device is a remote heat sink, wherein the remote heat sink is configured to receive the working fluid from a pump.

15. The immersion cooling unit of claim 13, wherein the dielectric working fluid does not immerse the condenser.

16. The immersion cooling unit of claim 12, wherein an operating temperature range is between 40° C. and 80° C.

17. The immersion cooling unit of claim 12, wherein the volume resistivity of the dielectric working fluid is at least 1×1010 Ω·cm.

18. The immersion cooling unit of claim 12, wherein the dielectric working fluid has a global warming potential (GWP) of less than 600.

19. The immersion cooling unit of claim 12, wherein the dielectric working fluid does not comprise a per- and polyfluoroalkyl substance (PFAS).

20. The immersion cooling unit of claim 12, wherein the electronic component comprises at least one component selected from the group consisting of high-capacity energy storage devices, computer servers, datacenter servers, GPUs, CPUs, solar photovoltaics, batteries, insulated-gate bipolar transistor (IGBT) devices, telecommunication in-frastructure, military electronics, televisions, cell phones, monitors, drones, automotive batteries, powertrains for electric vehicles, power electronics, avionics devices, power devices, power transformers, displays, microprocessors, wafers used to manufacture semiconductor devices, power control semiconductors, electrical distribution switch gear, circuit boards, multi-chip modules, packaged and unpackaged semiconductor devices, lasers, fuel cells, electrochemical cells, and combinations thereof.

21. The immersion cooling unit of claim 12, wherein the azeotropic or azeotrope-like composition comprises from about 19 weight percent to about 32 weight percent 1,1,2,2-tetrafluoroethyl-2,2,2-trifluoroethyl ether, and from 68 weight percent to about 81 weight percent perfluoroethyl isopropyl ketone.

22. The immersion cooling unit of claim 12, wherein the azeotropic or azeotrope-like composition comprises from about 27 weight percent to about 62 weight percent 1,1,2,2-tetrafluoroethyl-2,2,2-trifluoroethyl ether, and from about 38 weight percent to about 73 weight percent perfluorohexane.

23. The immersion cooling unit of claim 12, wherein the azeotropic or azeotrope-like composition comprises from about 22 weight percent to about 50 weight percent 1,1,2,2-tetrafluoroethyl-2,2,2-trifluoroethyl ether, and from about 50 weight percent to about 78 weight percent perfluoro(N-methylmorpholine).

24. The immersion cooling unit of claim 12, wherein the azeotropic or azeotrope-like composition comprises from about 48 weight percent to about 84 weight percent 1,1,2,2-tetrafluoroethyl-2,2,2-trifluoroethyl ether, and from about 16 weight percent to about 52 weight percent nonafluorobutyl methyl ether.

25. The immersion cooling unit of claim 12, wherein the azeotropic or azeotrope-like composition further comprises a component selected from the group consisting of linear hydrocarbons, cyclic hydrocarbons, cyclohexane, methylcyclohexane, n-heptane, and combinations thereof, wherein the azeotropic or azeotrope-like composition is a ternary azeotropic or azeotrope-like composition.

26. The immersion cooling unit of claim 12, wherein the azeotropic or azeotrope-like composition comprises from about 18 weight percent to about 26 weight percent 1,1,2,2-tetrafluoroethyl-2,2,2-trifluoroethyl ether, from about 63 weight percent to about 75 weight percent perfluoroethyl isopropyl ketone, and from about 4 weight percent to about 10 weight percent cyclohexane.

27. The immersion cooling unit of claim 12, wherein the azeotropic or azeotrope-like composition comprises from about 18 weight percent to about 30 weight percent 1,1,2,2-tetrafluoroethyl-2,2,2-trifluoroethyl ether, from about 67 weight percent to about 80 weight percent perfluoroethyl isopropyl ketone, and from about 1 weight percent to about 4 weight percent methylcyclohexane.

28. The immersion cooling unit of claim 12, wherein the azeotropic or azeotrope-like composition comprises from about 18 weight percent to about 30 weight percent 1,1,2,2-tetrafluoroethyl-2,2,2-trifluoroethyl ether, from about 68 weight percent to about 80 weight percent perfluoroethyl isopropyl ketone, and from about 1 weight percent to about 4 weight percent n-heptane.

29. The immersion cooling unit of claim 12, wherein the azeotropic or azeotrope-like composition comprises from about 20 weight percent to about 45 weight percent 1,1,2,2-tetrafluoroethyl-2,2,2-trifluoroethyl ether, from about 47 weight percent to about 74 weight percent perfluoro(N-methylmorpholine), and from about 4 weight percent to about 10 weight percent cyclohexane.

30. The immersion cooling unit of claim 12, wherein the azeotropic or azeotrope-like composition comprises from about 45 weight percent to about 80 weight percent 1,1,2,2-tetrafluoroethyl-2,2,2-trifluoroethyl ether, from about 15 weight percent to about 49 weight percent nonafluorobutyl methyl ether, and from about 2 weight percent to about 8 weight percent n-heptane.

31. A method for cooling an electrical component comprising:
at least partially immersing an electrical component in a working fluid; and
transferring heat from the electrical component using the working fluid;
wherein the working fluid comprises an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

32. The method of claim 31, wherein said transferring of heat occurs through pumping of said working fluid from the electrical component to be cooled to a remote heat sink.

33. The method of claim 31, wherein said transferring of heat occurs through vaporization of said working fluid in contact with the electrical component to be cooled, and condensing said working fluid vapor through contact with a heat sink.

34. The method of claim 31, wherein the azeotropic or azeotrope-like composition further comprises a component selected from the group consisting of linear hydrocarbons, cyclic hydrocarbons, cyclohexane, methylcyclohexane, n-heptane, and combinations thereof, wherein the azeotropic or azeotrope-like composition is a ternary azeotropic or azeotrope-like composition.

35. A method of replacing a dielectric fluid in an immersion cooling system, comprising:
charging an immersion cooling system that was designed for use with a working fluid with a composition comprising an azeotropic or azeotrope-like composition comprising 1,1,2,2-tetrafluoroethyl-2,2,2-trifluoroethyl ether and a component selected from the group consisting of perfluoroethyl isopropyl ketone, perfluorohexane, perfluoro(N-methylmorpholine), and nonafluorobutyl methyl ether.

36. The method of claim 35, wherein the electrical component to fluid thermal resistance of the replacement fluid is lower than or equivalent to said working fluid.

37. The method of claim 35, wherein the electrical component to fluid thermal resistance of the replacement fluid is no higher than 20% greater than that of said working fluid.

38. The method of claim 35, wherein the electrical component to fluid thermal resistance of the replacement fluid is no higher than 10% greater than that of said working fluid.
